(19) United States
(12) Patent Application Publication
(10) Pub. No.: US 2013/0318419 A1
(43) Pub. Date: Nov. 28, 2013

(54) FLASH MEMORY SYSTEM INCLUDING READ COUNTER LOGIC

(71) Applicants: Changkyu Seol, Gyeonggi-do (KR); Junjin Kong, Gyeonggi-do (KR); Hong Rak Son, Gyeonggi-do (KR)

(72) Inventors: Changkyu Seol, Gyeonggi-do (KR); Junjin Kong, Gyeonggi-do (KR); Hong Rak Son, Gyeonggi-do (KR)

(21) Appl. No.: 13/829,553

(22) Filed: Mar. 14, 2013

(30) Foreign Application Priority Data
May 22, 2012 (KR) 10-2012-0054330

(51) Int. Cl. G06F 11/14; G06F 12/02; H03M 13/05

(52) U.S. Cl. CPC G06F 11/1412; H03M 13/05; G06F 12/0246
USPC 714/773; 714/746; 711/103

(57) ABSTRACT

A flash memory system which includes a flash memory and a memory controller. The flash memory is configured to perform a read operation using a plurality of read levels. The memory controller is configured to recover original data using a counter value provided from the flash memory. The flash memory converts read result values obtained using the plurality of read levels into the counter value to provide the counter value to the memory controller.

### CROSS-REFERENCE TO RELATED APPLICATION

This U.S. non-provisional application claims priority under 35 U.S.C. §119 to Korean Patent Application No. 10-2012-0054330, filed May 22, 2012, in the Korean Intellectual Property Office, the disclosure of which is incorporated by reference herein in its entirety.

### BACKGROUND

1. Technical Field

The inventive concept relates to a semiconductor memory device, and more particularly, to a flash memory system including read counter logic.

2. Discussion of the Related Art

In general, semiconductor memory devices may include volatile memories such as dynamic random access memory (DRAM), static random access memory (SRAM), and the like, and nonvolatile memories such as electrically erasable programmable read only memory (EEPROM), ferroelectric random access memory (FRAM), phase-change random access memory (PRAM), magnetoresistive random access memory (MRAM), flash memory, and the like. While the volatile memories lose content stored therein when not powered, the nonvolatile memories may retain content stored therein when not powered. The flash memory may have a rapid read speed, low power consumption, large storage capacity, and the like. For at least these reasons, a flash memory based memory system (e.g., a flash memory system) may be widely used as a data storage medium.

A flash memory system may use a code modulation technique to improve the reliability of data. With the code modulation technique, the reliability of data may be improved through an error correction code and signal mapping. While the reliability of data is improved by the code modulation technique, the code modulation technique may cause the lowering of write and read speeds, thus lowering system performance.

### SUMMARY

An exemplary embodiment of the inventive concept provides a flash memory system which comprises a flash memory configured to perform a read operation using a plurality of read levels; and a memory controller configured to recover original data using a counter value provided from the flash memory, wherein the flash memory converts read result values obtained using the plurality of read levels into the counter value to provide the counter value to the memory controller.

In an exemplary embodiment of the inventive concept, the flash memory includes read counter logic configured to convert the read result values obtained using the plurality of read levels into the counter value.

In an exemplary embodiment of the inventive concept, the read counter logic includes a [log₂ n] bit counter, wherein n is the number of the plurality of read levels.

In an exemplary embodiment of the inventive concept, the counter value is 0 or 1.

In an exemplary embodiment of the inventive concept, the flash memory stores m-bit data in a memory cell, wherein m is an integer of 1 or more.

In an exemplary embodiment of the inventive concept, the memory controller includes a code modulation encoder configured to convert the original data into code modulation data.

In an exemplary embodiment of the inventive concept, the code modulation encoder comprises a bit divider which divides the original data into a plurality of messages; an error correction code (ECC) encoder which performs ECC encoding on each of the messages to output a code word associated with each of the messages; and a subset and state selector which performs a bit-state mapping operation on the code words to output the code modulation data.

In an exemplary embodiment of the inventive concept, the bit divider determines a size of each of the messages based on an error correction capacity of the ECC encoder.

In an exemplary embodiment of the inventive concept, the ECC encoder generates parities such that the code words associated with the messages have the same size.

In an exemplary embodiment of the inventive concept, the flash memory and the memory controller are included in a memory card.

In an exemplary embodiment of the inventive concept, the flash memory and the memory controller are included in a solid state drive.

In an exemplary embodiment of the inventive concept, the flash memory has a three-dimensional structure.

An exemplary embodiment of the inventive concept provides a flash memory which comprises a memory cell array configured to store data; and a control unit configured to perform a read operation using a plurality of read levels to read data stored in the memory cell array, wherein the control unit converts read result values obtained using the plurality of read levels into a counter value.

In an exemplary embodiment of the inventive concept, the control unit includes read counter logic configured to convert the read result values obtained using the plurality of read levels into the counter value.

In an exemplary embodiment of the inventive concept, the read counter logic includes a [log₂ n] bit counter, wherein n is the number of the plurality of read levels.

In an exemplary embodiment of the inventive concept, the counter value is provided to a memory controller.

In an exemplary embodiment of the inventive concept, the counter value is preset data.

An exemplary embodiment of the inventive concept provides a memory system that includes a nonvolatile memory configured to perform a plurality of read operations on a memory cell using a plurality of read levels and output data having a number of bits less than the number of read levels; and a memory controller configured to receive the data output from the nonvolatile memory.

In an exemplary embodiment of the inventive concept, [log₂ n]*N bits are transferred for a word line when the number of memory cells connected with the word line is N, wherein n is the number of the plurality of read levels.

In an exemplary embodiment of the inventive concept, the memory controller provides the nonvolatile memory with code modulation data including bit-state mapping information.

### BRIEF DESCRIPTION OF THE DRAWINGS

The above and other features of the inventive concept will become more apparent by describing in detail exemplary embodiments thereof with reference to the accompanying drawings, in which:

FIG. 1 is a block diagram illustrating a flash memory system according to an exemplary embodiment of the inventive concept.

FIG. 2 is a block diagram illustrating a code modulation encoder in FIG. 1, according to an exemplary embodiment of the inventive concept.

FIGS. 3 and 4 are diagrams illustrating a bit-state mapping method of a code modulation encoder in FIG. 2 and a mapping result, according to an exemplary embodiment of the inventive concept.

FIG. 5 is a diagram illustrating an error correction code (ECC) encoder designed according to a bit-state mapping method illustrated in FIG. 3, according to an exemplary embodiment of the inventive concept.

FIGS. 6 and 7 are diagrams illustrating levels for reading data stored at a flash memory according to a bit-state mapping method illustrated in FIG. 3, according to an exemplary embodiment of the inventive concept.

FIG. 8 is a block diagram illustrating a flash memory in FIG. 1, according to an exemplary embodiment of the inventive concept.

FIGS. 9 and 10 are diagrams illustrating an operation of read counter logic in FIG. 8, according to an exemplary embodiment of the inventive concept.

FIG. 11 is a flowchart illustrating an operating method of read counter logic in FIG. 8, according to an exemplary embodiment of the inventive concept.

FIG. 12 is a block diagram illustrating a memory card including a flash memory system according to an exemplary embodiment of the inventive concept.

FIG. 13 is a block diagram illustrating a solid state drive (SSD) system in which a memory system according to an exemplary embodiment of the inventive concept is applied.

FIG. 14 is a block diagram illustrating an SSD controller in FIG. 13, according to an exemplary embodiment of the inventive concept.

FIG. 15 is a block diagram illustrating an electronic device including a flash memory system according to an exemplary embodiment of the inventive concept.

FIG. 16 is a block diagram illustrating a flash memory applied to an exemplary embodiment of the inventive concept.

FIG. 17 is a perspective view illustrating a three-dimensional (3D) structure of a memory block illustrated in FIG. 16, according to an exemplary embodiment of the inventive concept.

FIG. 18 is a circuit diagram illustrating an equivalent circuit of a memory block illustrated in FIG. 17, according to an exemplary embodiment of the inventive concept.

### DETAILED DESCRIPTION OF THE EMBODIMENTS

Hereinafter, exemplary embodiments of the inventive concept will be described in detail with reference to the accompanying drawings. The inventive concept, however, may be embodied in various different forms, and should not be construed as being limited to the embodiments set forth herein. Like reference numerals may denote like elements, for example, layers or regions, throughout the attached drawings and written description. In the drawings, the sizes of elements may be exaggerated for clarity.

As used herein, the singular forms “a,” “an” and “the” are intended to include the plural forms as well, unless the context clearly indicates otherwise.

It will be understood that when an element is referred to as being “on,” “connected to,” “coupled to,” or “adjacent to” another element, it can be directly on, connected, coupled, or adjacent to the other element, or intervening elements may be present.

A memory system according to an exemplary embodiment of the inventive concept may use a code modulation technique to improve the reliability of data. Herein, the code modulation technique may be a signal processing technique applied to a flash memory system to improve the reliability of data through signal mapping. The signal mapping may mean a bit-state mapping operation for mapping a data bit onto a program state.

Below, a flash memory system using a code modulation technique according to an exemplary embodiment of the inventive concept will be described. A method of modulating original data or information bits into code modulation data and a bit-state mapping operation executed at the modulating operation according to an exemplary embodiment of the inventive concept will be described. In addition, a decoding method for recovering original data from data programmed at a flash memory according to an exemplary embodiment of the inventive concept will be described.

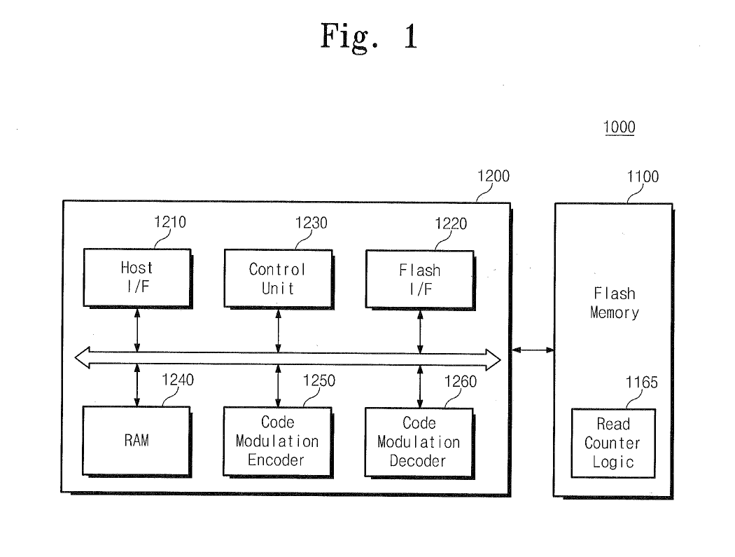

FIG. 1 is a block diagram illustrating a flash memory system according to an exemplary embodiment of the inventive concept. Referring to FIG. 1, a flash memory system 1000 may include a flash memory 1100 and a memory controller 1200. The flash memory system 1000 may include flash memory based data storage devices such as a memory card, a universal serial bus (USB) memory, a solid state drive (SSD), and the like.

The flash memory 1100 may perform an erase, write, or read operation under the control of the memory controller 1200. The flash memory 1100 may include a plurality of memory blocks, each of which is formed of a plurality of pages. Each page may be formed of a plurality of memory cells. The flash memory 1100 may perform an erase operation by the memory block and a write or read operation by the page.

A single data bit or two or more data bits (e.g., multi-bit data) may be stored at each memory cell of the flash memory 1100. A single level cell (SLC) flash memory for storing single bit data may have an erase state or a program state according to a threshold voltage distribution. A multi-level cell (MLC) flash memory for storing multi-bit data may have one of an erase state and program states according to a threshold voltage distribution. Below, exemplary embodiments of the inventive concept will be described using a 3-bit MLC flash memory. However, the inventive concept is not limited thereto. For example, exemplary embodiments of the inventive concept can be applied to an MLC flash memory which stores two data bits or four or more data bits per memory cell.

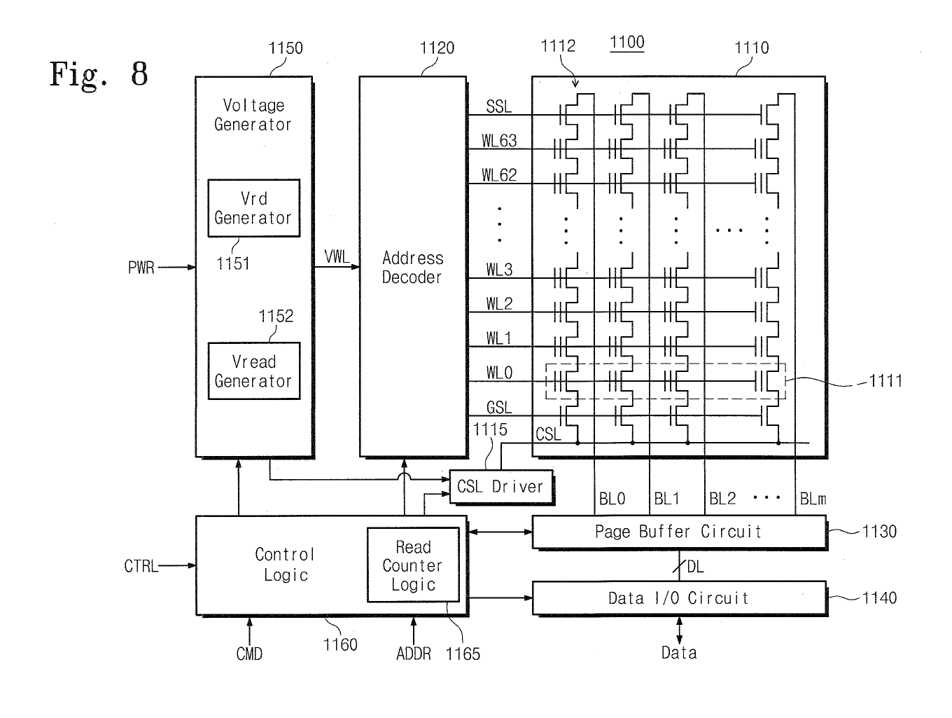

Referring to FIG. 1, the flash memory 1100 may include read counter logic 1165. In a case where data programmed to the flash memory 1100 in a code modulation technique is read, the read counter logic 1165 may be configured to reduce the amount of data to be programmed to the memory controller 1200. This will be more fully described with reference to FIG. 8.

The memory controller 1200 may control read and write operations of the flash memory 1100 in response to a request of an external device (e.g., a host). The memory controller 1200 may include a host interface 1210, a flash interface 1220, a control unit 1230, a random access memory (RAM) 1240, a code modulation encoder 1250, and a code modulation decoder 1260.

The host interface 1210 may interface with the external device (e.g., a host), and the flash interface 1220 may interface with the flash memory 1100. The host interface 1210 may be connected with the host via a parallel advanced technology attachment (ATA) bus, a serial ATA bus, a small computer system interface (SCSI), a USB, and the like.

The control unit 1230 may control an overall operation of the flash memory 1100 such as reading, writing, file system managing, and the like. For example, although not shown in FIG. 1, the control unit 1230 may include a central processing unit (CPU), a processor, a static random access memory (SRAM), a direct memory access (DMA) controller, and the like.

The RAM 1240 may operate responsive to the control of the control unit 1230, and may be used as a work memory, a buffer memory, a cache memory, and the like. The RAM 1240 may be formed of one chip or a plurality of chips each corresponding to areas of the flash memory 1100.

In the event that the RAM 1240 is used as a work memory, data processed by the control unit 1230 may be temporarily stored at the RAM 1240. When the RAM 1240 is used as a buffer memory, the RAM 1240 may be used to buffer data to be transferred from the host to the flash memory 1100 or from the flash memory 1100 to the host. If the RAM 1240 is used as a cache memory (e.g., a cache scheme), the RAM 1240 may enable the flash memory 1100 to operate with a high speed. A flash translation layer (FTL) may be used to manage a merge operation of the flash memory 1100, a mapping table, and the like.

The code modulation encoder 1250 may receive original data or information bits to generate an error correction code (ECC) for correcting error bits. Herein, the ECC may be referred to as an ECC parameter or parity. The code modulation encoder 1250 may perform error correction encoding to generate parity-added data (e.g., a code word). The parity may be stored at the flash memory 1100 with general data.

The code modulation decoder 1260 may recover original data from code modulation data. The code modulation decoder 1260 may perform error correction decoding on data read from the flash memory 1100, and may judge whether the error correction decoding is successful, according to the decoding result. The code modulation decoder 1260 may output an indication signal according to the judgment result, and may correct error bits of data using the parity.

The code modulation encoder 1250 and the code modulation decoder 1260 may be implemented by one module, and may perform an error correction function using LDPC (low density parity check) code, BCH (Bose, Chaudhuri, and Hocquenghem) code, turbo code, Reed-Solomon code, convolution code, RSC (recursive systematic code), TCM (trellis-coded modulation), BCM (Block coded modulation), and the like.

The flash memory system 1000 in FIG. 1 may generate code modulation data using the code modulation encoder 1250 and recover original data using the code modulation decoder 1260. When code modulation data is read from the flash memory 1100, the flash memory system 1000 may be configured to provide the number of a specific data value instead of the read data value. In this case, it is possible to reduce the amount of data to be transferred to the memory controller 1200 from the flash memory 1100.

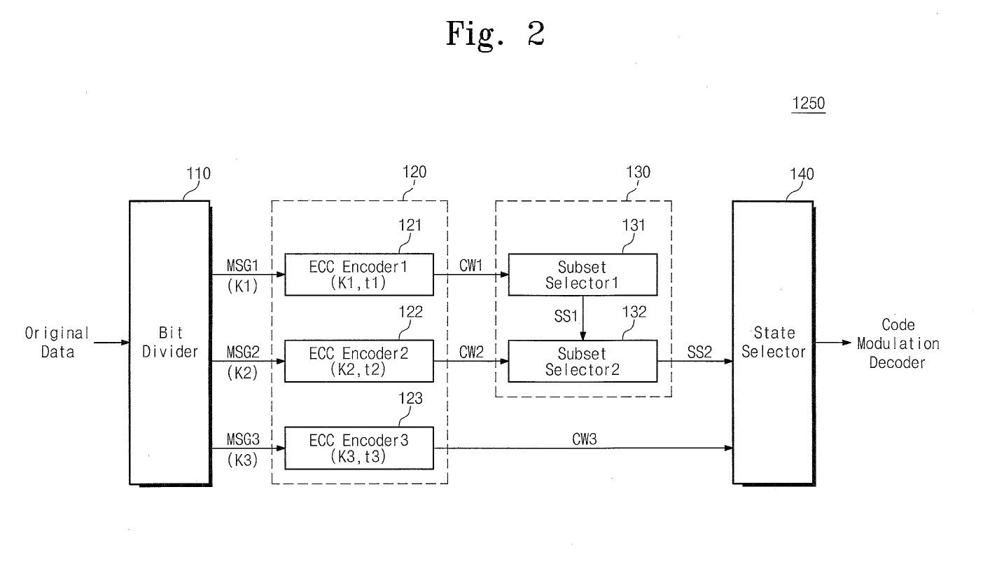

FIG. 2 is a block diagram illustrating the code modulation encoder in FIG. 1, according to an exemplary embodiment of the inventive concept. The code modulation encoder 1250 in FIG. 2 may receive original data to provide the flash memory 1100 with code modulation data having a mapping result between three bits and eight states. In FIG. 2, there may be illustrated an example of a 3-bit MLC flash memory.

Referring to FIG. 2, the code modulation encoder 1250 may include a bit divider 110, an ECC encoder 120, a subset selector 130, and a state selector 140. The code modulation encoder 1250 may receive original data to output code modulation data.

The bit divider 110 may divide the original data into three bit vectors. Herein, a bit vector may also be referred to as a message MSG. Messages may have the same size or different sizes. A size of each message may vary according to an error correction capacity of the ECC encoder 120.

In an exemplary embodiment of the inventive concept, original data may be divided into first, second, and third messages MSG1, MSG2, and MSG3. The first message MSG1 may have a size of K1, the second message MSG2 may have a size of K2, and the third message MSG3 may have a size of K3. The first to third messages MSG1 to MSG3 may be provided to the ECC encoder 120.

The ECC encoder 120 may generate code words CW having the same size by adding parities to the first to third messages MSG1 to MSG3, respectively. Note that the code words CW do not always have the same size.

The ECC encoder 120 may include first to third ECC encoders 121 to 123. The first to third ECC encoders 121 to 123 may have different error correction capacities. In FIG. 2, t1, t2, and t3 may indicate error correction capacities of the first, second, and third ECC encoders 121, 122, and 123.

The first ECC encoder 121 may be provided with the message MSG1 of the K1 size and have the error correction capacity of t1. The first ECC encoder 121 may generate a first parity having a p1 size to output a first code word CW1 having a (K1+p1) size. The second ECC encoder 122 may be provided with the message MSG2 of the K2 size and have the error correction capacity of t2. The second ECC encoder 122 may generate a second parity having a p2 size to output a second code word CW2 having a (K2+p2) size. The third ECC encoder 123 may be provided with the message MSG3 of the K3 size and have the error correction capacity of t3. The third ECC encoder 123 may generate a third parity having a p3 size to output a third code word CW3 having a (K3+p3) size. Herein, the first to third code words CW1 to CW3 may have the same size.

The subset selector 130 and the state selector 140 may perform a bit-state mapping operation for determining one of eight states in response to the first to third code words CW1 to CW3. Referring to FIG. 2, the subset selector 130 may include first and second subset selectors 131 and 132 over various levels. The subset selector 130 may select a subset according to data input at each level. Herein, the subset may mean a set of states. For example, a subset may include {E0, P2, P4, P6}, {P1, P3, P5, P7}, {E0, P4}, {P2, P6}, {P1, P5}, {P3, P7}, or the like.

The first subset selector 131 may sequentially receive the first code word CW1 bit by bit to select a first level subset according to an input data bit (‘1’ or ‘0’). For example, the first subset selector 131 may select {E0, P2, P4, P6} or {P1, P3, P5, P7} during a first level. The first subset selector 131 may perform an operation for selecting the first level subset by a size of the first code word CW1. The first subset selector 131 may provide first subset selection information SS1 to the second subset selector 132.

The second subset selector 132 may sequentially receive the second code word CW2 bit by bit. The second subset selector 132 may select a second level subset according to the first subset selection information SS1 and the second code word CW2. For example, the second subset selector 132 may select {E0, P4}, {P2, P6}, {P1, P5} or {P3, P7}. The second subset selector 132 may perform an operation for selecting the second level subset by a size of the second code word CW2. The second subset selector 132 may provide second subset selection information SS2 to the state selector 140.

The state selector 140 may sequentially receive the third code word CW3 bit by bit. The state selector 140 may select one of eight states E0 to P7 according to the second subset selection information SS2 and the third code word CW3. The state selector 140 may perform an operation for selecting a state by a size of the third code word CW3. The state selector 140 may provide the flash memory 1100 with code modulation data including bit-state mapping information.

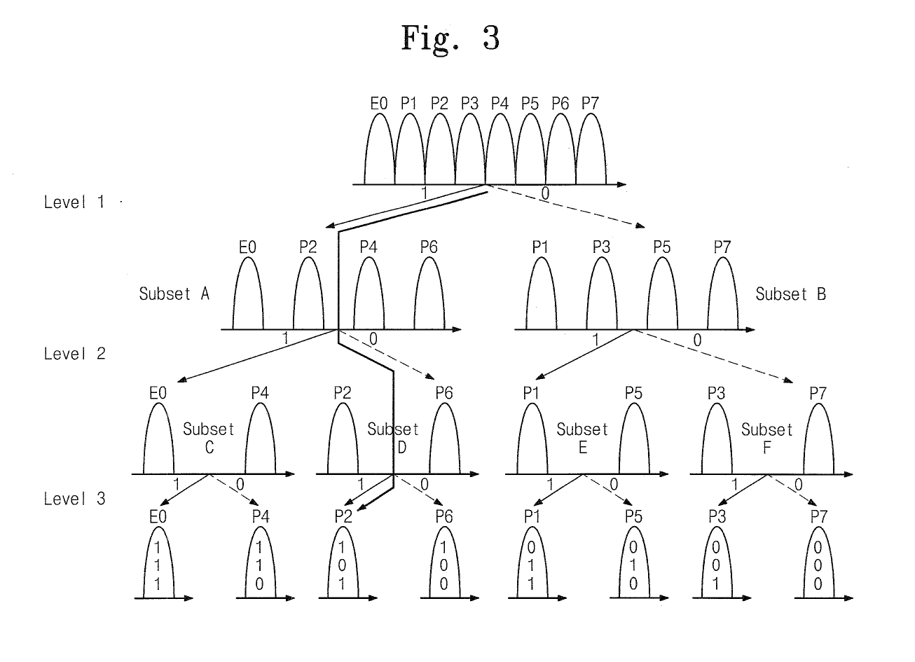

FIGS. 3 and 4 are diagrams illustrating a bit-state mapping method of a code modulation encoder in FIG. 2 and a mapping result, according to an exemplary embodiment of the inventive concept. A 3-bit MLC flash memory may have eight states E0 to P7, which are divided into lower subsets over plural levels through a set partitioning process.

In FIG. 3, an operation of mapping data of ‘101’ onto any state will be described (refer to a bold solid line). Herein, MSB data ‘1’ may be data that belongs to the first code word CW1 provided to the first subset selector 131. CSB data ‘0’ may be data that belongs to the second code word CW2 provided to the second subset selector 132. LSB data ‘1’ may be data that belongs to the third code word CW3 provided to the state selector 140. Herein, MSB data may be upper bit data, CSB data may be central bit data, and LSB data may be lower bit data.

During a first level Level 1, the first subset selector 131 may select a subset A or a subset B according to the MSB data. Herein, the subset A may be {E0, P2, P4, P6} and the subset B may be {P1, P3, P5, P7}. The subset A may be selected when the MSB data has a value of ‘1’ and the subset B may be selected when the MSB data has a value of ‘0.’ Since the MSB data has a value of ‘1,’ the subset A may be selected.

During a second level Level 2, the second subset selector 132 may select one of subsets C to F according to the CSB data. Herein, the subset C may be {E0, P4}, the subset D may be {P2, P6}, the subset E may be {P1, P5}, and the subset F may be {P3, P7}. It is assumed that the subset A is selected at the first level Level 1. In this case, the subset C may be selected when the CSB data has a value of ‘1’ and the subset D may be selected when the CSB data has a value of ‘0.’ If the subset B is selected at the first level Level 1, the subset E may be selected when the CSB data has a value of ‘1’ and the subset F may be selected when the CSB data has a value of ‘0.’ Since the subset A was selected at the first level Level 1 and the CSB data has a value of ‘0,’ the subset D may be selected at the second level Level 2.

At a third level Level 3, the state selector 140 may select one of the eight states E0 to P7 according to a subset selected at the second level Level 2 and LSB data. Since the subset D was selected at the second level and the LSB data has a value of ‘1,’ a second program state P2 may be selected at the third level Level 3. Thus, data ‘101’ may be mapped onto the program state P2.

As understood from the above description, 3-bit data may be mapped onto one of the eight states. Referring to FIG. 4, ‘111,’ ‘011,’ ‘101,’ ‘001,’ ‘110,’ ‘010,’ ‘100,’ and ‘000’ may be mapped onto the states E0, P1, P2, P3, P4, P5, P6, and P7, respectively. 3-bit data may have different states according to a bit-state mapping method.

Returning to FIG. 3, as a level increases, a gap between states within each subset may increase. It is assumed that a gap between states at an initial state is d. With this assumption, a gap between states within each subset may be 2d at the first level Level 1. At the subset A, a gap between adjacent states among states E0, P2, P4, and P6 may be 2d. At the subset B, a gap between adjacent states among states P1, P3, P5, and P7 may be 2d. A gap between states within each subset may be 4d at the second level Level 2. A gap between states E0 and P4 at the subset C, a gap between states P2 and P6 at the subset D, a gap between states P1 and P5 at the subset E, and a gap between states P3 and P7 at the subset F may, be 4d, respectively.

Since a gap between states widens toward a lower level, it is possible to lower an error correction capacity of an ECC encoder. In FIG. 2, the error correction capacity t2 of the second ECC encoder 122 may be less than the error correction capacity t1 of the first ECC encoder 121. The error correction capacity t3 of the third ECC encoder 123 may be less than the error correction capacity t2 of the second ECC encoder 122. With the above-described bit-state mapping method, the reliability of data may be secured and an ECC encoder may be designed more efficiently.

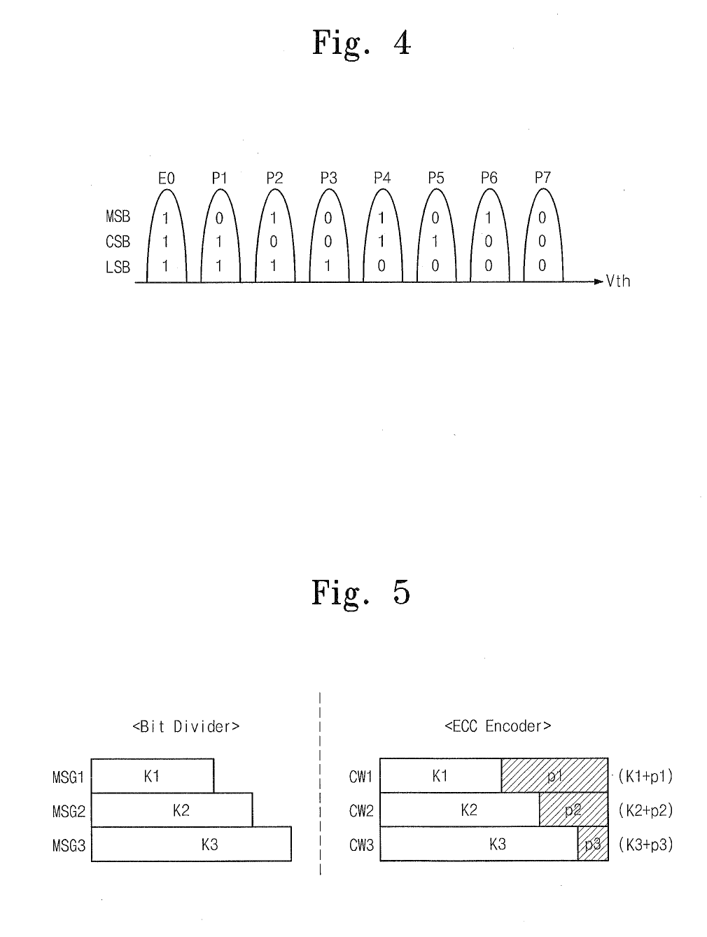

FIG. 5 is a diagram illustrating an ECC encoder designed according to a bit-state mapping method illustrated in FIG. 3, according to an exemplary embodiment of the inventive concept. Referring to FIG. 5, the bit divider 110 may divide original data such that the first message MSG1 has the smallest size K1 and the third message MSG3 has the largest size K3, in light of the condition that a gap between states widens toward a lower level. In other words, the bit divider 110 may determine a message size such as K1<K2<K3.

The ECC encoder 120 may be configured such that the first ECC encoder 121 has the highest error correction level (or, capacity) and the third ECC encoder 123 has the lowest error correction level (or, capacity). As described above, a code word may be formed of a message and a parity. Code words may have the same size. Thus, the first parity size p1 may be largest, and the third parity size p3 may be smallest. In other words, parity sizes may have a correlation such as p1>p2>p3.

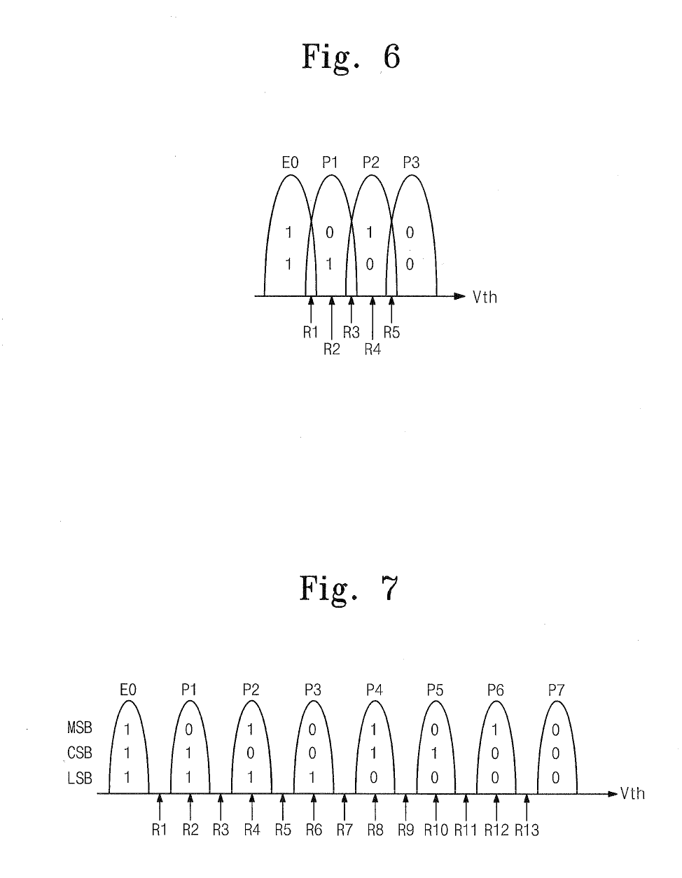

FIGS. 6 and 7 are diagrams illustrating levels for reading data stored at a flash memory according to a bit-state mapping method illustrated in FIG. 3, according to an exemplary embodiment of the inventive concept. FIG. 6 shows an example of a 2-bit MLC flash memory, and FIG. 7 shows an example of a 3-bit MLC flash memory.

Referring to FIG. 6, whether MSB data is ‘0’ or ‘1’ may be determined according to results of read operations executed using read levels R1, R3, and R5. Whether LSB data is ‘0’ or ‘1’ may be determined according to the MSB data and results of read operations executed using read levels R2 and R4. In a case where MSB data is determined to be ‘1,’ LSB data may be determined according to a value read from a flash memory that corresponds to an erase state E0 or to a program state P2.

A read operation may be additionally executed at a central point (a center of a program P1 state) between centers of the erase E0 and program P2 states to minimize a detection error associated with the erase E0 and program P2 states. If MSB data is ‘1,’ a read operation may be additionally executed at a central point (a center of the program P2 state) between centers of the program P1 and program P3 states.

As illustrated in FIG. 6, a flash memory storing 2-bit data in a memory cell may perform read operations using read levels R1 to R5 by a word line unit to secure the reliability of data. Referring to FIG. 7, in the case of a 3-bit MLC flash memory, read operations may be performed using 13 read levels R1 to R13. In the case of a 4-bit MLC flash memory, read operations may be performed using 29 read levels.

FIG. 8 is a block diagram illustrating the flash memory in FIG. 1, according to an exemplary embodiment of the inventive concept. Referring to FIG. 8, the flash memory 1100 may include a memory cell array 1110, an address decoder 1120, a page buffer circuit 1130, a data input/output circuit 1140, a voltage generator 1150, and control logic 1160.

The memory cell array 1110 may be formed of a plurality of memory blocks. In FIG. 8, there is exemplarily illustrated one memory block. Each memory block may be formed of a plurality of physical pages. Herein, a physical page may indicate a set of memory cells connected with one word line. In FIG. 8, a reference numeral 1111 may indicate a physical page. Each physical page may be formed of a plurality of memory cells, each of which includes a cell transistor having a control gate and a floating gate.

The memory cell array 1110 may be formed of a plurality of cell strings. Each cell string may include a string selection transistor connected with a string selection line SSL, a plurality of memory cells connected with a plurality of word lines WL0 to WL63, and a ground selection transistor connected with a ground selection line GSL. In each cell string, the string selection transistor may be connected with a bit line (e.g., one of BL0 to BLm), and the ground selection transistor may be connected with a common source line CSL.

The address decoder 1120 may be connected with the memory cell array 1110 via the selection lines SSL and GSL and the word lines WL0 to WL63. At a read or program operation, the address decoder 1120 may select one word line (e.g., WL0) in response to an address ADDR.

The page buffer circuit 1130 may be connected with the memory cell array 1110 via the bit lines BL0 to BLm. The page buffer circuit 1130 may include a plurality of page buffers (not shown), each of which is connected with one bit line (e.g., an all bit line structure) or two bit lines (e.g., a shield bit line structure). The page buffer circuit 1130 may temporarily store data to be programmed at the selected page 1111 or read from the selected page 1111.

The data input/output circuit 1140 may be connected with the page buffer circuit 1130 via data lines DL and with the memory controller 1200 (refer to FIG. 1) via input/output lines. At a program operation, the data input/output circuit 1140 may receive program data from the memory controller 1200. At a read operation, the data input/output circuit 1140 may provide read data to the memory controller 1200.

The voltage generator 1150 may receive power PWR from the memory controller 1200 to generate a word line voltage VWL for reading or programming. The word line voltage VWL may be provided to the address decoder 1120. As illustrated in FIG. 8, the voltage generator 1150 may include a selection read voltage generator 1151 and a non-selection read voltage generator 1152.

The selection read voltage generator 1151 may generate a selection read voltage Vrd to be provided to a selected word line (e.g., WL0). The non-selection read voltage generator 1152 may generate a non-selection read voltage Vread to be provided to unselected word lines (e.g., WL1 to WL63). The non-selection read voltage Vread may have a level sufficient to turn on a memory cell in a cell string.

The control logic 1160 may control reading, programming, and erasing of the flash memory 1100 using a command CMD, the address ADDR, and a control signal CTRL. For example, at a read operation, the control logic 1160 may control the address decoder 1120 such that the selection read voltage Vrd or the non-selection read voltage Vread is provided to the selected word line (e.g., WL0) and control the page buffer circuit 1130 and the data input/output circuit 1140 such that data programmed at the selected page 1111 is read.

The control logic 1160 may include read counter logic 1165. The read counter logic 1165 may perform a data conversion on a result of a read operation executed within the flash memory 1100. In this case, a data transfer amount between the flash memory 1100 and the memory controller 1200 may be reduced. A common source line (CSL) driver 1115 may be configured to drive the common source line CSL of the memory cell array 1100 with a voltage from the voltage generator 1150 under the control of the control logic 1160.

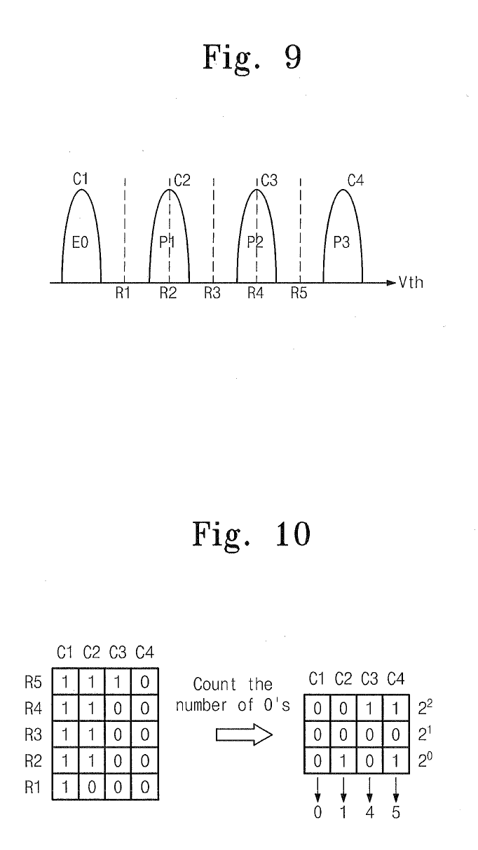

FIGS. 9 and 10 are diagrams illustrating an operation of read counter logic in FIG. 8, according to an exemplary embodiment of the inventive concept. In a case where the flash memory 1100 is a 2-bit MLC flash memory, each memory cell may have one of four states E0, P1, P2, and P3. As described above, read operations may be performed using five read levels R1 to R5 to read code modulation data. When read operations are performed using five read levels R1 to R5, respectively, 5-bit data may be output from a memory cell. For example, it is assumed that four memory cells C1 to C4 have threshold voltages Vth as illustrated in FIG. 9.

In FIG. 10, a left-side table may show result values of read operations performed using first to fifth read levels R1 to R5. When read operations are performed using the first to fifth read levels R1 to R5, values output from the memory cell C1 all may include five ‘1’ values (the number of ‘0’ values output is zero), values output from the memory cell C2 may include four ‘1’ values (the number of ‘0’ values output is 1), values output from the memory cell C3 may include one ‘1’ value (the number of ‘0’ values output is 4), and values output from the memory cell C4 may not include a ‘1’ value (the number of ‘0’ values output is 5).

In FIG. 10, a right-side table may show the number of data ‘0’ (or, ‘1’) values output from the memory cells C1 to C4 with respect to the results of the read operations executed using the first to fifth read level R1 to R5. The number of read operations executed with respect to the memory cell C1 may indicate ‘000,’ and the number of read operations executed with respect to the memory cell C2 may indicate ‘001.’ The number of read operations executed with respect to the memory cell C3 may indicate ‘100,’ and the number of read operations executed with respect to the memory cell C4 may indicate ‘101.’

In the case of a conventional 2-bit MLC flash memory, since results obtained via five read operations may be output, 5-bit data may be output from each memory cell. On the other hand, the flash memory according to an exemplary embodiment of the inventive concept may output 3-bit data per memory cell by performing a data conversion using the read counter logic 1165. Thus, it is possible to reduce a data transfer amount and to improve the performance of a system.

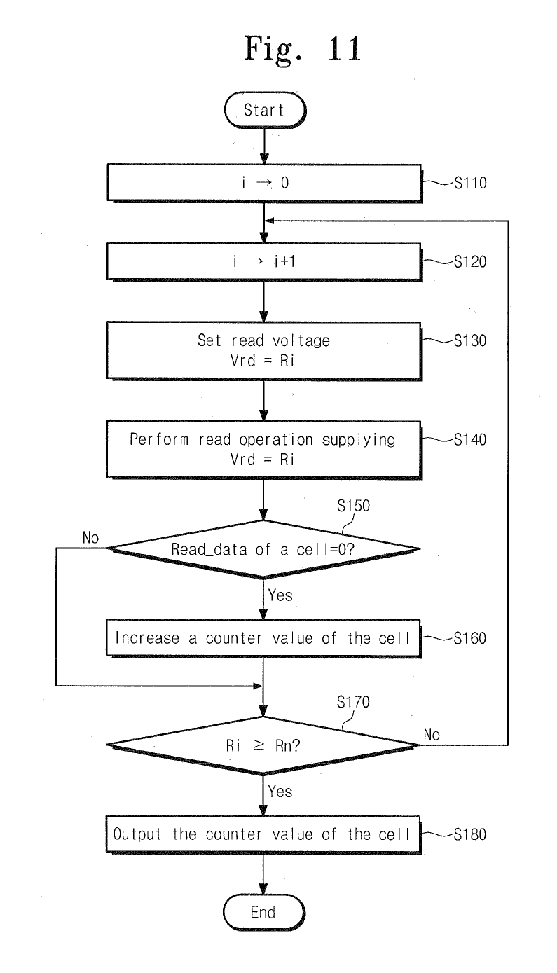

FIG. 11 is a flowchart illustrating an operating method of the read counter logic in FIG. 8, according to an exemplary embodiment of the inventive concept. Referring to FIG. 11, in operation S110, a variable i may be reset to ‘0.’ In operation S120, the variable i may increase by one ‘i+1.’ In operation 5130, a read voltage Vrd may be set to an ith read level Ri. If I=1, the read voltage Vrd may be set to a first read level R1. In operation S 140, a read operation may be performed using the read level Ri. In other words, a selection read voltage Vrd may be provided to a selected word line.

In operation S150, whether read data of a memory cell is ‘0’ may be judged. If the read data is ‘0,’ the method proceeds to operation 5160, in which a counter value of the memory cell may increase. If the read data is not ‘0,’ the method proceeds to operation S 170, in which it is judged whether a value of the variable i is a final value. For example, is Ri≧Rn? If the value of the variable i is not the final value, the method proceeds to operation S120. The operations S120 to S170 may be repeated until a value of the variable i reaches the final value. If the value of the variable i is the final value, in operation S 180, a counter value of the memory cell may be output.

Read counter logic 1165 in FIG. 8 may convert a read data result into a read counter value according to the method described with reference to FIG. 11. An operating method of the read counter logic 1165 may not be limited to that described in this disclosure. A method of reducing a data bit number via data conversion may be changed or modified variously.

The read counter logic 1165 may be configured to include a [log₂ n] bit counter. Herein, n may indicate the number of read levels. A function [x] may indicate a minimum value among integers larger than or equal to x. For example, [x] may be 2. In the case that five read levels are used, the read counter logic 1165 may be configured to include a 3-bit counter ([log₂ 5]=3).

The flash memory system 1000 according to an exemplary embodiment of the inventive concept may reduce a data transfer amount between the flash memory 1100 and the memory controller 1200. In a conventional manner, n*N bits may be transferred over every word line when the number of memory cells connected with a word line is N. On the other hand, in case of the flash memory system according to an exemplary embodiment of the inventive concept, [log₂ n]*N bits may be transferred.

A memory system according to an exemplary embodiment of the inventive concept may be applied to various products. The memory system according to an exemplary embodiment of the inventive concept may be used as electronic devices such as a personal computer, a digital camera, a camcorder, a portable telephone, an MP3 player, a portable media player (PMP), a playstation portable (PSP), a personal digital assistant (PDA), and storage devices such as a memory card, a USB memory, an SSD, and the like.

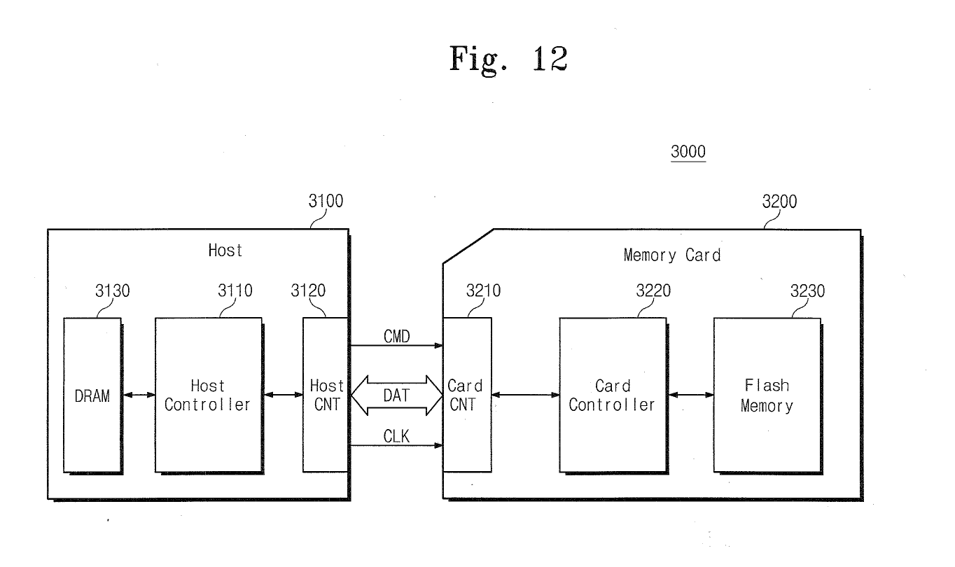

FIG. 12 is a block diagram illustrating a memory card including a flash memory system according to an exemplary embodiment of the inventive concept. A memory card system 3000 may include a host 3100 and a memory card 3200. The host 3100 may include a host controller 3110, a host connection unit 3120, and a dynamic random access memory (DRAM) 3130.

The host 3100 may write data to the memory card 3200 and read data from the memory card 3200. The host controller 3110 may send a command CMD (e.g., a write command), a clock signal CLK generated from a clock generator (not shown) in the host 3100, and data DATA to the memory card 3200 via the host connection unit 3120. The DRAM 3130 may be a main memory of the host 3100.

The memory card 3200 may include a card connection unit 3210, a card controller 3220, and a flash memory 3230. The card controller 3220 may store data in the flash memory 3230 in response to a command input via the card connection unit 3210. The data may be stored in synchronization with a clock signal generated from a clock generator (not shown) in the card controller 3220. The flash memory 3230 may store data transferred from the host 3100. For example, in a case where the host 3100 is a digital camera, the flash memory 3230 may store image data.

In the case of the memory card system 3000 in FIG. 12, the flash memory 3230 may include read counter logic (1165, refer to FIG. 1), and the card controller 3220 may include a code modulation encoder (1250, refer to FIG. 1) and a code modulation decoder (1260, refer to FIG. 1). Through the above-described bit-state mapping method, the memory card system 3000 according to an exemplary embodiment of the inventive concept may maintain the reliability of data and reduce a read data transfer amount.

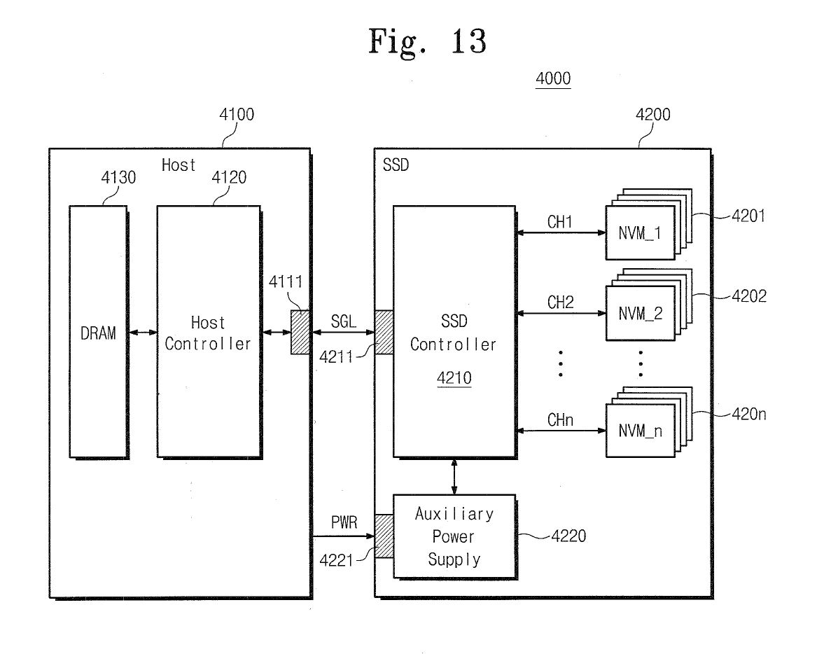

FIG. 13 is a block diagram illustrating an SSD system in which a memory system according to an exemplary embodiment of the inventive concept is applied. Referring to FIG. 13, an SSD system 4000 may include a host 4100 and an SSD 4200. The host 4100 may include a host interface 4111, a host controller 4120, and a DRAM 4130.

The host 4100 may write data in the SSD 4200 or read data from the SSD 4200. The host controller 4120 may transfer signals SGL such as a command, an address, a control signal, and the like to the SSD 4200 via the host interface 4111. The DRAM 4130 may be a main memory of the host 4100.

The SSD 4200 may exchange signals SGL with the host 4100 via the host interface 4111, and may be supplied with power PWR via a power connector 4221. The SSD 4200 may include a plurality of nonvolatile memories 4201 to 420n, an SSD controller 4210, and an auxiliary power supply 4220. Herein, the nonvolatile memories 4201 to 420n may be implemented by a NAND flash memory and other nonvolatile memories such as phase-change random access memory (PRAM), magnetoresistive random access memory (MRAM), resistive random access memory (ReRAM), and the like.

The plurality of nonvolatile memories 4201 to 420n may be used as a storage medium of the SSD 4200. The plurality of nonvolatile memories 4201 to 420n may be connected with the SSD controller 4210 via a plurality of channels CH1 to CHn. One channel may be connected with one or more nonvolatile memories. Nonvolatile memories connected with one channel may be connected with the same data bus.

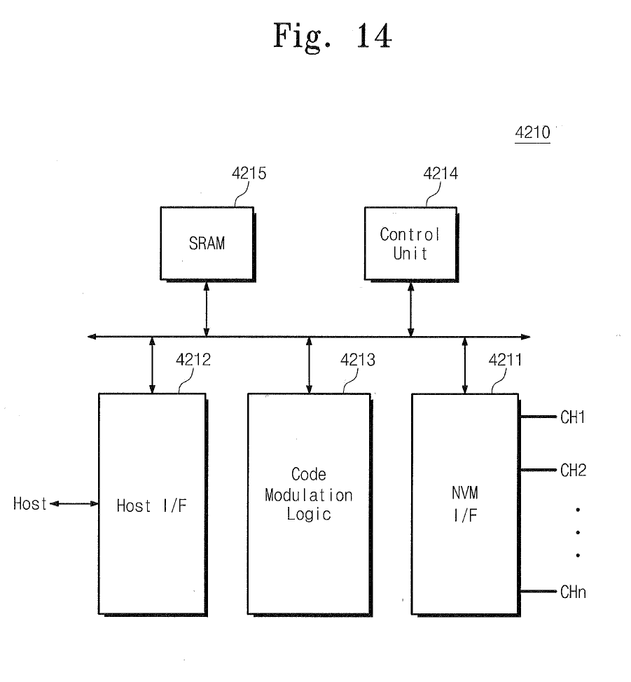

The SSD controller 4210 may exchange the signals SGL with the host 4100 via the host interface 4211. Herein, the signals SGL may include a command, an address, data, and the like. The SSD controller 4210 may be configured to write or read data to or from a corresponding nonvolatile memory according to a command of the host 4100. The SSD controller 4210 will be more fully described with reference to FIG. 14.

The auxiliary power supply 4220 may be connected with the host 4100 via the power connector 4221. The auxiliary power supply 4220 may be charged by the power PWR provided from the host 4100. The auxiliary power supply 4220 may be placed inside or outside the SSD 4200. For example, the auxiliary power supply 4220 may be put on a main board to supply auxiliary power to the SSD 4200.

FIG. 14 is a block diagram illustrating the SSD controller in FIG. 13, according to an exemplary embodiment of the inventive concept. Referring to FIG. 14, the SSD controller 4210 may include a nonvolatile memory (NVM) interface 4211, a host interface 4212, code modulation logic 4213, a control unit 4214, and an SRAM 4215.

The NVM interface 4211 may scatter data transferred from a main memory of the host 4100 to the channels CH1 to CHn, respectively. The NVM interface 4211 may transfer data read from the nonvolatile memories 4201 to 420n to the host 4100 via the host interface 4212.

The host interface 4212 may provide an interface with the SSD 4200 according to the protocol of the host 4100. The host interface 4212 may communicate with the host 4100 using USB, SCSI, peripheral component interconnect (PCI) express, ATA, PATA (Parallel ATA), SATA (Serial ATA), SAS (Serial Attached SCSI), etc. The host interface 4212 may perform a disk emulation function which enables the host 4100 to recognize the SSD 4200 as a hard disk drive (HDD).

The code modulation logic 4213 may include the code modulation encoder 1250 and the code modulation decoder 1260 described with reference to FIG. 1. The control unit 4214 may analyze and process a signal SGL input from the host 4100. The control unit 4214 may control the host 4100 or the nonvolatile memories 4201 to 420n via the host interface 4212 or the NVM interface 4211. The control unit 4214 may control the nonvolatile memories 4201 to 420n according to firmware for driving the SSD 4200.

The SRAM 4215 may be used to drive software which efficiently manages the nonvolatile memories 4201 to 420n. The SRAM 4215 may store metadata input from a main memory of the host 4100 or cache data. At a sudden power-off operation, metadata or cache data stored in the SRAM 4215 may be stored in the nonvolatile memories 4201 to 420n using the auxiliary power supply 4220.

The SSD system 4000 in FIG. 13 may use read counter logic, a code modulation encoder, and a code modulation decoder to perform code modulation on original data or to recover original data from code modulation data. An exemplary embodiment of the inventive concept may maintain the reliability of data and reduce a read data transfer amount.

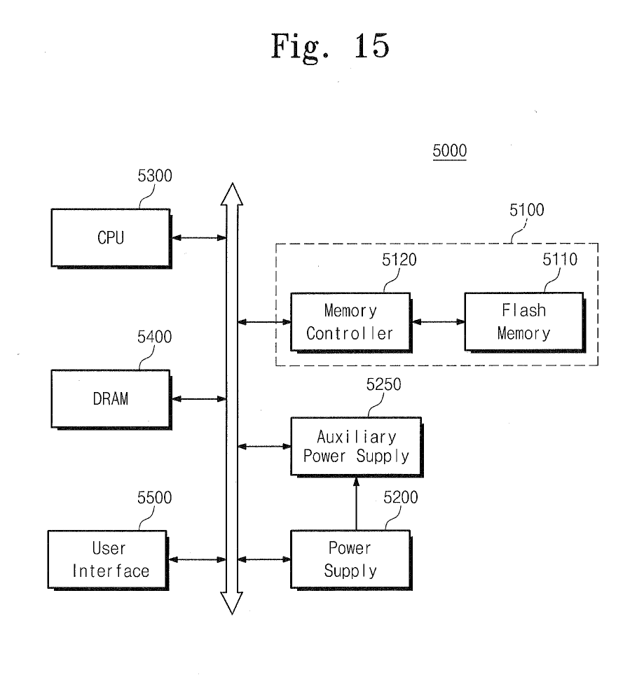

FIG. 15 is a block diagram illustrating an electronic device including a flash memory system according to an exemplary embodiment of the inventive concept. Herein, an electronic device 5000 may be a personal computer or a handheld electronic device such as a notebook computer, a cellular phone, a PDA, a camera, and the like.

Referring to FIG. 15, the electronic device 5000 may include a memory system 5100, a power supply device 5200, an auxiliary power supply 5250, a CPU 5300, a DRAM 5400, and a user interface 5500. The memory system 5100 may include a flash memory 5110 and a memory controller 5120. The memory system 5100 can be embedded within the electronic device 5000.

The electronic device 5000 according to an exemplary embodiment of the inventive concept may use read counter logic, a code modulation encoder, and a code modulation decoder to perform code modulation on original data or to recover original data from code modulation data. An exemplary embodiment of the inventive concept may reduce a read data transfer amount.

A memory system according to an exemplary embodiment of the inventive concept is applicable to a flash memory having a three-dimensional (3D) structure as well as a flash memory having a two-dimensional (2D) structure.

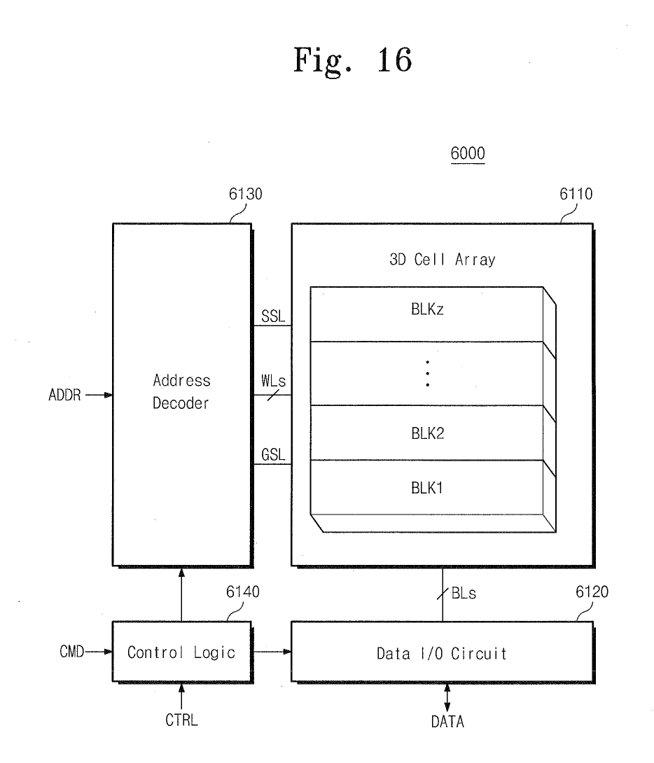

FIG. 16 is a block diagram illustrating a flash memory applied to an exemplary embodiment of the inventive concept. Referring to FIG. 16, a flash memory 6000 may include a 3D cell array 6110, a data input/output circuit 6120, an address decoder 6130, and control logic 6140.

The 3D cell array 6110 may include a plurality of memory blocks BLK1 to BLKz, each of which is formed to have a 3D structure (or, a vertical structure). For a memory block having a 2D (e.g., horizontal) structure, memory cells may be formed in a direction horizontal with respect to a substrate. For a memory block having a 3D structure, memory cells may be formed in a direction perpendicular to the substrate. Each memory block may be an erase unit of the flash memory 6000.

The data input/output circuit 6120 may be connected with the 3D cell array 6110 via a plurality of bit lines BLs. The data input/output circuit 6120 may receive data DATA from an external device or output data DATA read from the 3D cell array 6110 to the external device. The address decoder 6130 may be connected with the 3D cell array 6110 via a plurality of word lines WLs and selection lines GSL and SSL. The address decoder 6130 may select the word lines WLs in response to an address ADDR.

The control logic 6140 may control programming, erasing, reading, etc. of the flash memory 6000 in response to a command CMD and a control signal CTRL. For example, at programming, the control logic 6140 may control the address decoder 6130 such that a program voltage is supplied to a selected word line, and may control the data input/output circuit 6120 such that data is programmed.

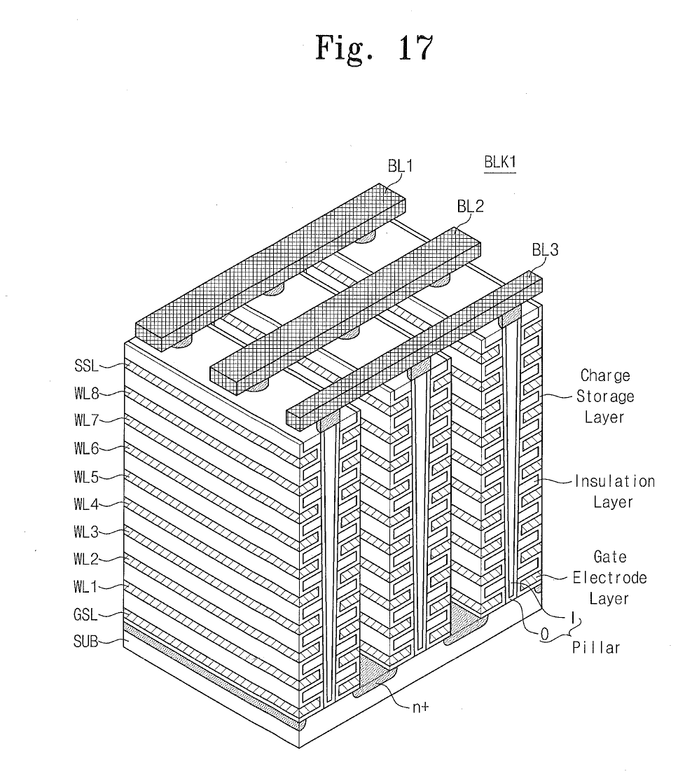

FIG. 17 is a perspective view illustrating a 3D structure of a memory block illustrated in FIG. 16, according to an exemplary embodiment of the inventive concept. Referring to FIG. 17, a memory block BLK1 may be formed in a direction perpendicular to a substrate SUB. An n+doping region may be formed at the substrate SUB. A gate electrode layer and an insulation layer may be deposited on the substrate SUB in sequence. A charge storage layer may be formed between the gate electrode layer and the insulation layer.

If the gate electrode layer and the insulation layer are patterned in a vertical direction, a V-shaped pillar may be formed. The pillar may be connected with the substrate SUB via the gate electrode layer and the insulation layer. An outer portion O of the pillar may be formed of a channel semiconductor, and an inner portion I of the pillar may be formed of an insulation material such as silicon oxide.

The gate electrode layer of the memory block BLK1 may be connected with a ground selection line GSL, a plurality of word lines WL1 to WL8, and a string selection line SSL. The pillar of the memory block BLK1 may be connected with a plurality of bit lines BL1 to BL3. In FIG. 17, there is illustrated the case that one memory block BLK1 has two selection lines SSL and GSL, eight word lines WL1 to WL8, and three bit lines BL1 to BL3. However, the inventive concept is not limited thereto.

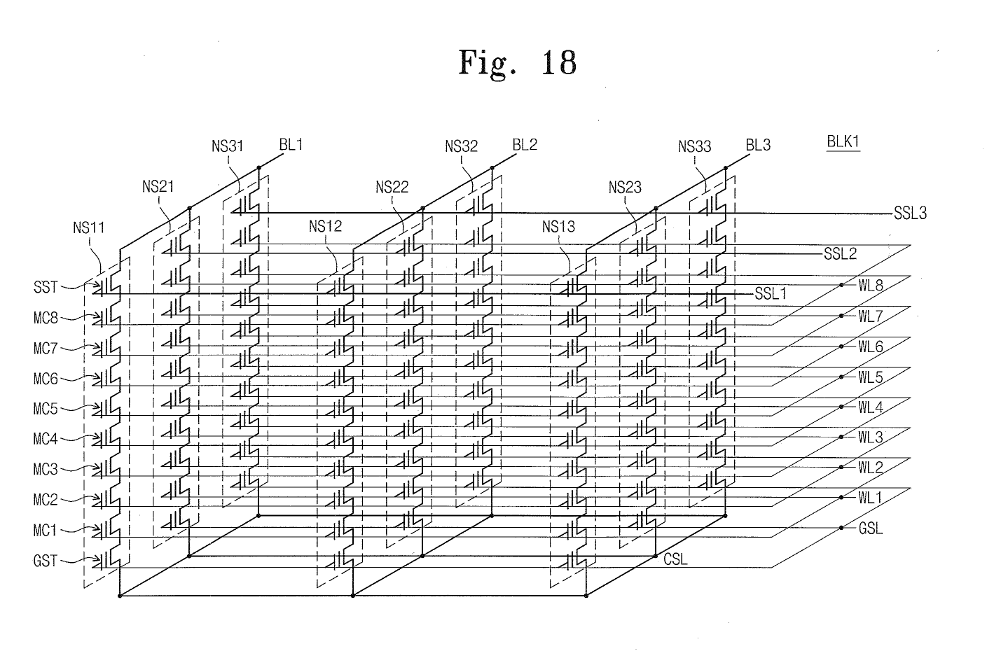

FIG. 18 is a circuit diagram illustrating an equivalent circuit of a memory block illustrated in FIG. 17, according to an exemplary embodiment of the inventive concept. Referring to FIG. 18, NAND strings NS11 to NS33 may be connected between bit lines BL1 to BL3 and a common source line CSL. Each NAND string (e.g., NS11) may include a string selection transistor SST, a plurality of memory cells MC1 to MC8, and a ground selection transistor GST.

The string selection transistors SST may be connected with string selection lines SSL1 to SSL3. The memory cells MC1 to MC8 may be connected with corresponding word lines WL1 to WL8, respectively. The ground selection transistors GST may be connected with ground selection line GSL. A string selection transistor SST may be connected with a bit line (BL1 to BL3) and a ground selection transistor GST may be connected with the common source line CSL.

Word lines (e.g., WL1) having the same height may be connected in common, and the string selection lines SSL1 to SSL3 may be separated from one another. At programming of memory cells (constituting a page) connected with a first word line WL1 and included in NAND strings NS11, NS12, and NS13, there may be selected the first word line WL1 and a first string selection line SSL1.

While the inventive concept has been shown and described with reference to exemplary embodiments thereof, it will be apparent to those of ordinary skill in the art that various changes in form and detail may be made thereto without departing from the spirit and scope of the inventive concept as defined by the following claims.

What is claimed is:

1. A flash memory system, comprising:
a flash memory configured to perform a read operation using a plurality of read levels; and
a memory controller configured to recover original data using a counter value provided from the flash memory,
wherein the flash memory converts read result values obtained using the plurality of read levels into the counter value to provide the counter value to the memory controller.

2. The flash memory system of claim 1, wherein the flash memory includes:
read counter logic configured to convert the read result values obtained using the plurality of read levels into the counter value.

3. The flash memory system of claim 2, wherein the read counter logic includes a [log₂ n] bit counter, wherein n is the number of the plurality of read levels.

4. The flash memory system of claim 2, wherein the counter value is 0 or 1.

5. The flash memory system of claim 1, wherein the flash memory stores m-bit data in a memory cell, wherein m is an integer of 1 or more.

6. The flash memory system of claim 1, wherein the memory controller includes:
a code modulation encoder configured to convert the original data into code modulation data.

7. The flash memory system of claim 6, wherein the code modulation encoder comprises:
a bit divider which divides the original data into a plurality of messages;
an error correction code (ECC) encoder which performs ECC encoding on each of the messages to output a code word associated with each of the messages; and
a subset and state selector which performs a bit-state mapping operation on the code words to output the code modulation data.

8. The flash memory system of claim 7, wherein the bit divider determines a size of each of the messages based on an error correction capacity of the ECC encoder.

9. The flash memory system of claim 8, wherein the ECC encoder generates parities such that the code words associated with the messages have the same size.

10. The flash memory system of claim 1, wherein the flash memory and the memory controller are included in a memory card.

11. The flash memory system of claim 1, wherein the flash memory and the memory controller are included in a solid state drive.

12. The flash memory system of claim 1, wherein the flash memory has a three-dimensional structure.

13. A flash memory, comprising:
a memory cell array configured to store data; and
a control unit configured to perform a read operation using a plurality of read levels to read data stored in the memory cell array,
wherein the control unit converts read result values obtained using the plurality of read levels into a counter value.

14. The flash memory of claim 13, wherein the control unit includes:
read counter logic configured to convert the read result values obtained using the plurality of read levels into the counter value.

15. The flash memory system of claim 14, wherein the read counter logic includes a [log₂ n] bit counter, wherein n is the number of the plurality of read levels.

16. The flash memory system of claim 13, wherein the counter value is provided to a memory controller.

17. The flash memory system of claim 13, wherein the counter value is preset data.

18. A memory system, comprising:
a nonvolatile memory configured to perform a plurality of read operations on a memory cell using a plurality of read levels and output data having a number of bits less than the number of read levels; and
a memory controller configured to receive the data output from the nonvolatile memory.

19. The memory system of claim 18, wherein [log₂ n]*N bits are transferred for a word line when the number of memory cells connected with the word line is N, wherein n is the number of the plurality of read levels.

20. The memory system of claim 18, wherein the memory controller provides the nonvolatile memory with code modulation data including bit-state mapping information.
